(19) United States
(12) Patent Application Publication
(10) Pub. No.: US 2012/0118369 A1
(43) Pub. Date: May 17, 2012

(54) SOLAR CELL ARCHITECTURE HAVING A PLURALITY OF VIAS WITH SHAPED FOIL VIA INTERIOR

(76) Inventors: Justin Hedtke, San Jose, CA (US); Jeremy H. Scholz, Sunnyvale, CA (US); Christoph Georg Erben, Los Gatos, CA (US)

(21) Appl. No.: 13/275,269

(22) Filed: Oct. 17, 2011

Related U.S. Application Data
(60) Provisional application No. 61/393,854, filed on Oct. 15, 2010.

(51) Int. Cl. H01L 31/0224; H01L 31/18

(52) U.S. Cl. 136/256; 438/57

(57) ABSTRACT

Methods and devices are provided for forming a low electrical resistance via filling material based on foil deformation.

### RELATED APPLICATIONS

The present application claims priority to U.S. Provisional Application 61/393,854, filed Oct. 15, 2010, and entitled “SOLAR CELL ARCHITECTURE HAVING A PLURALITY VIAS WITH SHAPED FOIL VIA INTERIOR”, which is fully incorporated herein by reference for all purposes.

### FIELD OF THE INVENTION

This invention relates to optoelectronic devices and more particularly to the electrical interconnection of layers within optoelectronic devices such as solar cells.

### BACKGROUND OF THE INVENTION

Optoelectronic devices can convert radiant energy into electrical energy or vice versa. These devices generally include an active layer sandwiched between two electrodes, sometimes referred to as the front and back electrodes, at least one of which is typically transparent. The active layer typically includes one or more semiconductor materials. In a light-emitting device, e.g., a light-emitting diode (LED), a voltage applied between the two electrodes causes a current to flow through the active layer. The current causes the active layer to emit light. In a photovoltaic device, e.g., a solar cell, the active layer absorbs energy from light and converts this energy to electrical energy exhibited as a voltage and/or current between the two electrodes. Large scale arrays of such solar cells can potentially replace conventional electrical generating plants that rely on the burning of fossil fuels. However, in order for solar cells to provide a cost-effective alternative to conventional electric power generation the cost per watt generated may be competitive with current electric grid rates. Currently, there are a number of technical challenges to attaining this goal.

Most conventional solar cells rely on silicon-based semiconductors. In a typical silicon-based solar cell, a layer of n-type silicon (sometimes referred to as the emitter layer) is deposited on a layer of p-type silicon. Radiation absorbed proximate to the junction between the p-type and n-type layers generates electrons and holes. The electrons are collected by an electrode in contact with the n-type layer and the holes are collected by an electrode in contact with the p-type layer. Since light may reach the junction, at least one of the electrodes may be at least partially transparent. Many current solar cell designs use a transparent conductive oxide (TCO) such as indium tin oxide (ITO) as a transparent electrode.

A further problem associated with existing solar fabrication techniques arises from the fact that individual optoelectronic devices produce only a relatively small voltage. Thus, it is often necessary to electrically connect several devices together in series in order to obtain higher voltages in order to take advantage of the efficiencies associated with high voltage, low current operation (e.g. power transmission through a circuit using relatively higher voltage, which reduces resistive losses that would otherwise occur during power transmission through a circuit using relatively higher current).

Several designs have been previously developed to interconnect solar cells into modules. For example, early photovoltaic module manufacturers attempted to use a “shingling” approach to interconnect solar cells, with the bottom of one cell placed on the top edge of the next, similar to the way shingles are laid on a roof. Unfortunately the solder and silicon wafer materials were not compatible. The differing rates of thermal expansion between silicon and solder and the rigidity of the wafers caused premature failure of the solder joints with temperature cycling.

A further problem associated with series interconnection of optoelectronic devices arises from the high electrical resistivity associated with the TCO used in the transparent electrode. The high resistivity restricts the size of the individual cells that are connected in series. To carry the current from one cell to the next the transparent electrode is often augmented with a conductive grid of busses and fingers formed on a TCO layer. However, the fingers and busses produce shadowing that reduces the overall efficiency of the cell. In order for the efficiency losses from resistance and shadowing to be small, the cells may be relatively small. Consequently, a large number of small cells may be connected together, which requires a large number of interconnects and more space between cells. Arrays of large numbers of small cells are relatively difficult and expensive to manufacture. Further, with flexible solar modules, shingling is also disadvantageous in that the interconnection of a large number of shingles is relatively complex, time-consuming and labor-intensive, and therefore costly during the module installation process.

To overcome this, optoelectronic devices have been developed with electrically isolated conductive contacts that pass through the cell from a transparent “front” electrode through the active layer and the “back” electrode to an electrically isolated electrode located beneath the back electrode. U.S. Pat. No. 3,903,427 describes an example of the use of such contacts in silicon-based solar cells. Although this technique does reduce resistive losses and can improve the overall efficiency of solar cell devices, the costs of silicon-based solar cells remains high due to the vacuum processing techniques used in fabricating the cells as well as the expense of thick, single-crystal silicon wafers. However, even these designs involve more elaborate manufacturing techniques and increased cost due to the cell architecture.

Due to the aforementioned issues, techniques are desired to improve photovoltaic cells manufacturing.

### SUMMARY OF THE INVENTION

Embodiments of the present invention address at least some of the drawbacks set forth above. Embodiments of the present invention provide an improved solar cell construction. In one non-limiting example, this may be accomplished by constructing a solar cell with an electrically isolated electrode located beneath the back electrode that is shaped to minimize the distance between such electrode and the front electrode. Some embodiments may decrease the cost of making the conductive pathway from the front electrode to the isolated back electrode. Optionally, some may improve the manufacturing of such solar cells. Optionally, some may decrease the resistive losses of such conductive pathway. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a solar cell is provided comprising a first metal substrate supporting an absorber layer thereon, wherein the metal substrate includes a plurality of vias extending through the first metal substrate; a second electrically conductive substrate having a plurality of protrusions on at least one surface of the second electrically conductive substrate, the protrusions positioned to extend into the vias of the first metal substrate; and an electrically insulating layer positioned to prevent direct electrical contact between a bottom surface of the first metal substrate and an upper surface of second electrically conductive substrate.

It should be understood that embodiments of the present invention may be adapted to have one or more of the feature herein. By way of non-limiting example, the protrusions have a cross-sectional profile with a hollow interior. Optionally, the protrusions are solid. Optionally, the protrusions are configured to reduce a top-side fill volume in each via. Optionally, the protrusions are configured to reduce a top-side fill volume in each via by at least 50%. Optionally, the protrusions are configured to reduce a top-side fill volume in each via by at least 75%. Optionally, the protrusions are configured to reduce a top-side fill volume in each via by at least 90% relative to completely filling each via without a protrusion therein. Optionally, the first metal substrate comprises one or more discrete layers formed over a bulk portion of the first metal substrate. Optionally, the second electrically conductive substrate has at least one high electrical conductivity on exposed surfaces of protrusions extending into the vias. Optionally, the second electrically conductive substrate has at least one high electrical conductivity silver-based layer on exposed surfaces of protrusions extending into the vias. Optionally, the protrusions comprises multiple metals. Optionally, the second electrically conductive substrate has at least one high electrical conductivity nickel-based layer on exposed surfaces of protrusions extending into the vias. Optionally, the protrusions extending into the vias has a cone-like shape. Optionally, the protrusions extending into the vias has a pyramid-like shape. Optionally, the protrusions extending into the vias has a cylindrical shape. Optionally, the protrusions when inserted into the via, has an uppermost portion above an uppermost surface of first metal substrate. Optionally, the protrusions when inserted into the via, has an uppermost portion below an uppermost surface of first metal substrate.

In another embodiment of the present invention, a method is provided comprising constructing a solar cell with a conductive pathway between two vertically separated electrode layers creating protrusion in electrode material in at least one of the layers to extend through vias in the other electrode layer.

It should be understood that embodiments of the present invention may be adapted to have one or more of the feature herein. By way of non-limiting example, the method may include creating the protrusions in the electrode material comprises using a punch to deform the electrode material. Optionally, creating the protrusions in the electrode material comprises using a plurality of punches to deform the electrode material in a roll-to-roll processing.

Optionally, creating the protrusions in the electrode material comprises using a plurality of punches to deform the electrode material in step-and-repeat processing. Optionally, creating the protrusions in the electrode material occurs before lamination of the electrode materials. Optionally, making the connection between a electrode layer of the solar cell and the protrusion in the via occurs by filling residual void in the via with electrically conductive material. Optionally, making the connection between a transparent electrode layer of the solar cell and the protrusion in the via occurs by filling residual void in the via with electrically conductive ink. Optionally, making the connection between a transparent electrode layer of the solar cell and the protrusion in the via occurs by screen printing a connection. Optionally, making the connection between a transparent electrode layer of the solar cell and the protrusion in the via occurs by using grid ink to bridge a gap between the protrusion and the transparent electrode. Optionally, making the connection occurs by using at least one of the following: using a wire for the grid, using TCO as the grid, or using nanowires/nanotubes as grid. Optionally, using the protrusion reduces resistive loss. Optionally, the method uses a rivet to make connection between the second electrically conductive substrate and an electrode layer of the solar cell. Optionally, the method includes filling any void formed in a hollow portion in any of the protrusions.

In another embodiment of the present invention, a solar cell is provide with at least one conductive pathway between two vertically separated and electrically isolated electrode layers with at least one protrusion in electrode material in at least one of the electrode layers to extend through vias in the other electrode layer. In one embodiment, the protrusion provides the electrical pathway.

A further understanding of the nature and advantages of the invention will become apparent by reference to the remaining portions of the specification and drawings.

### BRIEF DESCRIPTION OF THE DRAWINGS

FIG. 1 shows a side view of a solar cell with an isolated back contact electrode;

FIG. 2 shows a top view of a solar cell with an isolated back contact electrode;

FIGS. 3 to 5 illustrate methods of making an improved structure for such solar cell according embodiments of the present invention; and

FIGS. 6 to 7 show side cross-sectional views of solar cells according to embodiments of the present invention.

FIGS. 8 to 10 show side cross-sectional views of protrusions in substrates according to embodiments of the present invention.

FIGS. 11 and 12 show plugs or rivets for use according to embodiments of the present invention.

FIG. 13 shows a top down view of a via with a shaped protrusion and electrical traces over the protrusion according to embodiments of the present invention.

FIGS. 14 and 15 show selective placement of additional material at locations with protrusions are located according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

In one embodiment of the present invention, back contact thin film solar cell structures and processes are described. In this embodiment of the solar cell structure, the transparent electrode is electrically connected through vias to a backside electrode, which is a metal foil that is capable of carrying more current than the transparent electrode and costs much less. This allows a thinner, less expensive top electrode, and also affords much greater design flexibility for the cell and module.

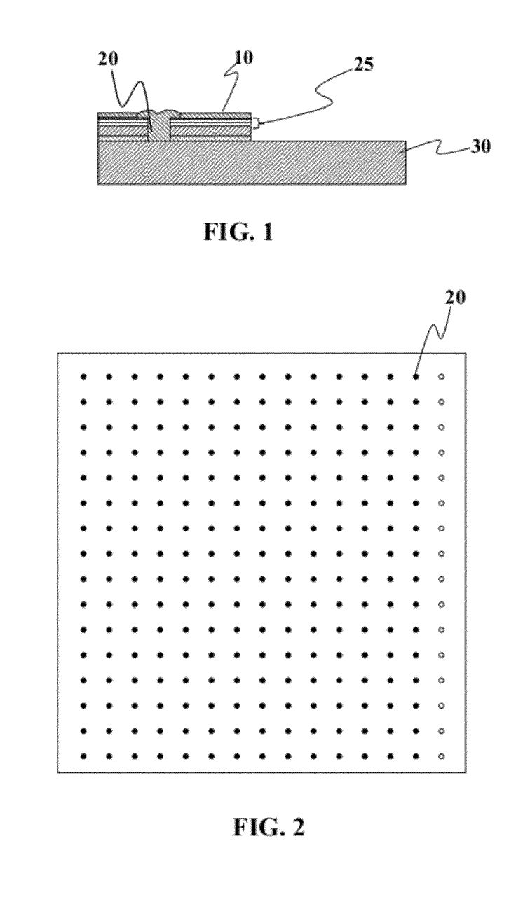

Referring now to FIG. 1, a cross-sectional view of the current state-of-the-art for a solar cell with an isolated back contact electrode. Although the electrically conductive, high light transmission layer 10 is shown with the present solar cell structure, it should be understood that such a layer 10 can be used in any solar cell that employs a conventional window layer. In this current embodiment, the layer 10 will be in contact with electrically conductive material 20 in vias that coupled to an electrically conductive back side layer 30. In some embodiments, the vias are only partially filled (or only side walls coated) with electrically conductive material. The active layer 25 is beneath the layer 10 and the increased light transmission of overlying layer 10 will increase either the active area of the active layer 25, increase the amount of light transmitted to the active layer 25, or both. Additional details regarding the cell structure may be found in U.S. patent application Ser. No. 11/278,645 filed Apr. 4, 2006 and fully incorporated herein by reference for all purposes. The substrate 30 (which is layer 110 in subsequent embodiments) may extend to be beneath the layer 106 of an adjacent solar cell.

FIG. 2 shows a top down plan view of one embodiment of a partially completed solar cell showing an array of vias fully filled and/or only partially filled with electrically conductive material. In some other embodiments, there may be electrically conductive traces or fingers extending outward such as but not limited to radially from each of the filled vias. These traces or fingers are typically formed of opaque electrically conductive material such as epoxy based silver inks The patterns of protrusions formed in the substrate can configured to match the repeating pattern or other array of vias in the solar cell.

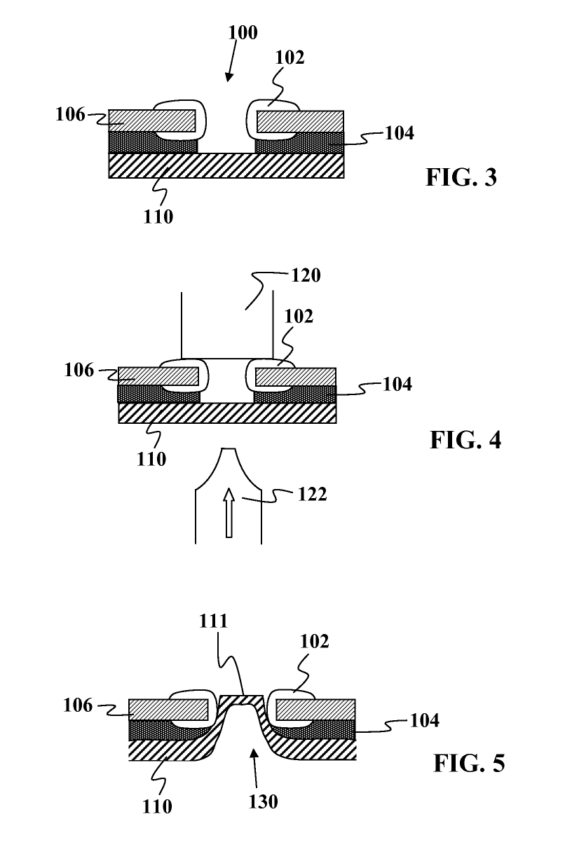

Referring now to FIG. 3, one embodiment of the present invention will now be described. FIG. 3 shows a cross-sectional view of a portion of a solar cell with a via 100. An electrically insulating material 102 may be included to cover all or at least a portion of the side walls of via 100. Another or same insulator may be used in layer 104 to separate the foil 106 with the photovoltaic active layer from a second electrically conductive metal foil 110. In one embodiment, the substrate 106 comprises at least one material selected from the group of copper, aluminum, steel, stainless steel, chromium, molybdenum, or other metal material. Some embodiments may use a material such as polyimide or the like. In one embodiment, the substrate 110 comprises at least one material selected from the group of copper, aluminum, steel, stainless steel, chromium, molybdenum, or other metal material. In one embodiment, both substrates 106 and 110 comprise stainless steel (although substrate 110 may be coated with a layer such as aluminum or silver that is more electrically conductive. Optionally, both substrates 106 and 110 comprise aluminum. Optionally, substrates 106 comprise stainless steel (although substrate 106 may be coated with a layer such as aluminum or silver that is more electrically conductive) and substrate 110 comprise aluminum.

FIG. 4 shows that the embodiment of FIG. 3 can be processed using a protrusion forming device. In this current embodiment, an anvil 120 is included above the via 100 and a shaped former 122 is located below. The anvil 120 may have a face surface that is shaped to create the desired “peak” of the protrusion 111 in the foil 110. Relative motion is created such that the former 122 will contact the foil 110 and deform the foil 110 to extend into the via 100. The anvil 120 is there so that foil 110 can form against it to create a flat surface or optionally just to prevent overpenetration by former 122 which would pierce the foil. Some embodiments have an anvil that fits inside the diameter of the via and this can limit the foil to a level below the top surface of the upper foil. Some embodiments can use an anvil 120 that is larger than the diameter of the via 100 or is at or above the top surface of the top of the solar cell on foil 106.

As the location of protrusion 111, FIG. 5 shows that the foil 110 creates a cavity 130 below and on the underside of the foil 110. This creates benefit in that the foil 110 now substantially occupies at least 75% of the interior of the via 100. The amount of space left in the via 100 is 50% or less than the volume in the via before deformation. Optionally, the amount of space left in the via 100 is 40% or less than the volume in the via before deformation. Optionally, the amount of space left in the via 100 is 30% or less than the volume in the via before deformation. Optionally, the amount of space left in the via 100 is 20% or less than the volume in the via before deformation. Optionally, the amount of space left in the via 100 is 15% or less than the volume in the via before deformation. Optionally, the amount of space left in the via 100 is 10% or less than the volume in the via before deformation. Optionally, the amount of space left in the via 100 is 5% or less than the volume in the via before deformation of the flat foil. This reduces the amount of material that is needed to fill the via 100, which can create significant cost savings as that ink is often silver ink that carries significant cost. Some embodiments are designed so that the protrusion of foil 110 is sized to extend beyond an upper surface of the layers of material on foil 106. Some embodiments may only fill the void with with material up to a portion that is lower than the top of layer 10. Another layer (not shown) may then be overlaid both layer 10 and the fill material and the protrusion to make the electrical connection. Some embodiments may have layer 10 making direct contact with the protrusion, such as by way of shaping the protrusion or with deposition of layer 10 in a manner to make the connection.

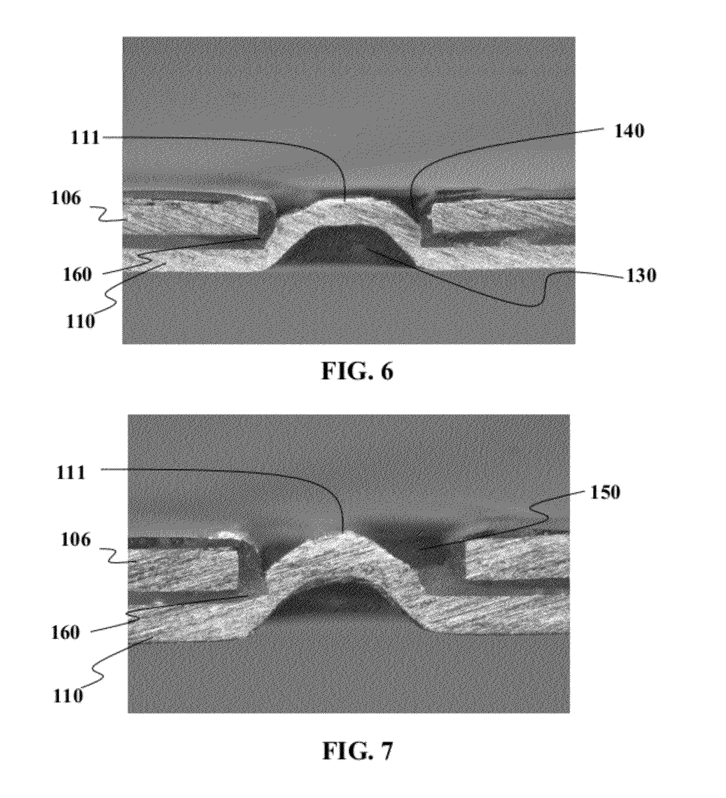

FIGS. 6 and 7 show optical microscope cross-sections of vias showing that the amount of space left to be filled 140 and 150 is significantly reduced by having a shaped foil extending into the via. In this embodiment, the overall foil thickness in the area of the protrusion is not substantially changed. Electrically insulating material at the corners 160 of the via on the bottom are positioned so that no electrical shorting occurs at those locations between the foils 106 and 110.

In one embodiment, the shaped foil at protrusion 111 can be only of rounded shape so that no sharp points are created that can cause shorting. Some may have a flat top as shown in FIG. 6. Some may have a more rounded shape as shown in FIG. 7. Other shapes for the tops of the protrusion may include, rounded, undulating, pointed, concave, or convex. Optionally, the top is shaped to have at least one surface that facilitates electrical connection between a solution deposited electrical conductor deposited in and/or over the via. Optionally, the top is shaped to have at least one surface that facilitates electrical connection between a physical structure that is soldered, welded, ultrasonically welded, laser welded, adhered, or otherwise attached to form an electrical pathway between the protrusion and a top transparent electrode.

The underside of the foil where cavity 130 is located can remain empty or can be filled by material prior to lamination of the cells into solar panel so as to reduce cost of panel encapsulant used to fill those holes. Some embodiments may pre-fill these voids 130 before joining the foil 110 with foil 106. Optionally, the voids 130 may be filled a void-filling material after the foils are laminated. Some embodiments may fill the voids 130 during the module encapsulation step, wherein the module encapsulant will fill the voids 130.

Some embodiments may have pre-shaped foils with protrusions that are registered to fit inside each via. Thus, the protrusions 111 in foil 110 can be made singly or in matrix (1×1, 4×4, 4×8, 8×8, etc . . . ) or by roller and then joined with the foil 106. Optionally, protrusions in foil 110 can be made singly or in matrix or by roller after being joined with the foil 106.

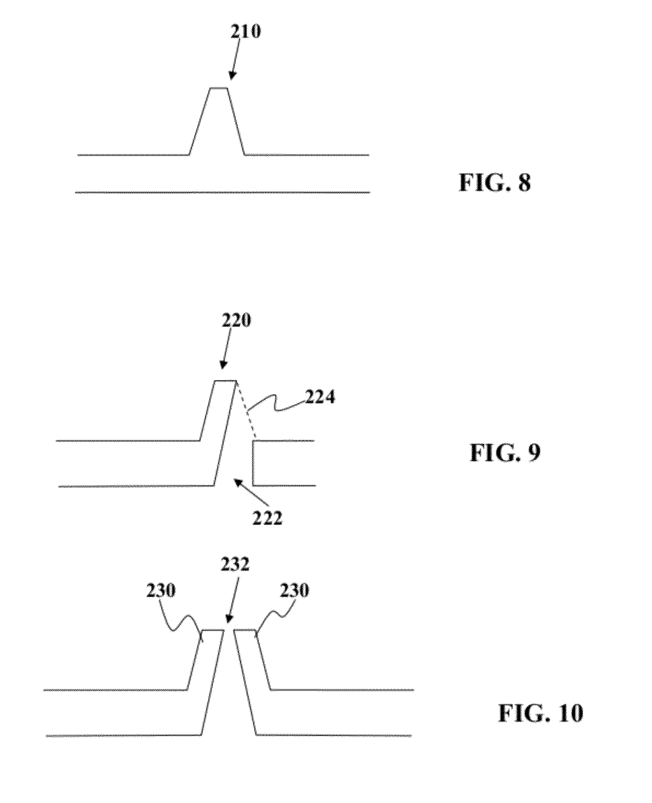

Referring now to FIGS. 8 to 10, side views of various other embodiments of protrusions for use with some embodiment of the present invention will now be described. FIG. 8 shows an embodiment wherein the protrusion 210 is a solid protrusion without a hollowed core. The protrusion 210 may be incorporated into the second substrate by a variety of techniques, including but not limited to rolling a thicker substrate to thin other areas except those for the location of the protrusions 210. Optionally, some may add the protrusions 210 to the substrate at a later point in time.

FIG. 9 shows an embodiment wherein the protrusions 220 may be burrs, points, or extensions made in the substrate. This embodiment differs in that there is an opening 222 that is formed when protrusion 220 is formed. Some embodiments may close these openings using welding techniques, filling with electrically conductive material, filling with electrically insulating material, or deforming material near the opening 222 to close it. Closing the opening can result in a filling that is the same plane as the substrate or optionally may be angled as indicated by line 224 to reduce the volume.

FIG. 10 shows yet another embodiment wherein there is a plurality of burrs, points, deformations, or extensions in the substrate, which form protrusions 230. This embodiment may be similar to that of FIG. 9 except that there are more burrs, points, deformations, or extensions per via. The opening 232 can be there or it can be closed or sealed as desired using techniques known by those skilled in the art.

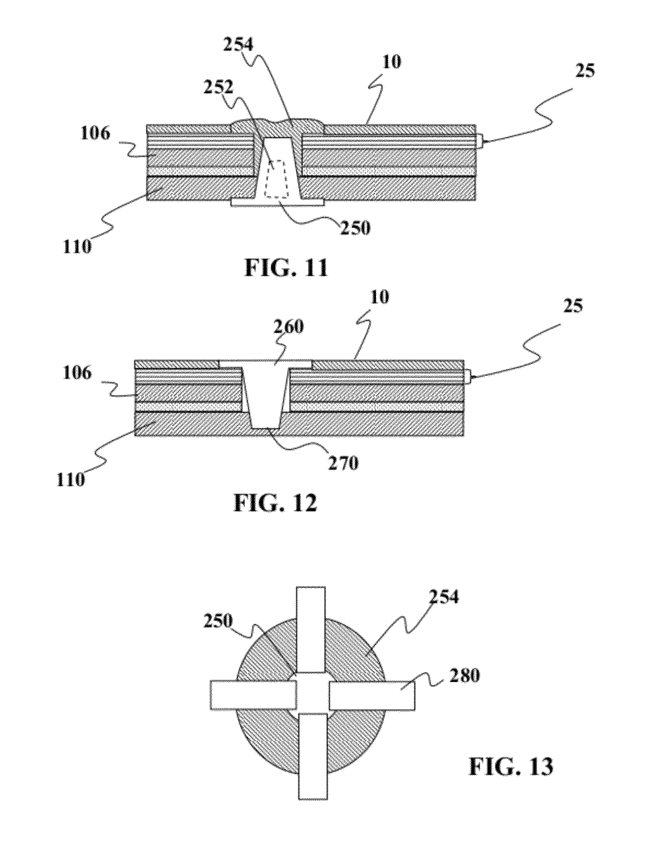

FIG. 11 shows a side cross-sectional view of yet another embodiment of the present invention. The side walls of the via may be coated with electrically insulating material (not shown for ease of illustration) or have sufficient spacing to prevent electrical connection to the protrusion by layers of the solar cell except by the designated electrode layer and/or finger traces/busbars associated with the electrode layer. This electrically insulated or electrically isolated side wall may be true of any of the embodiments in this application.

This embodiment uses a plug, rivet, or other additional element as protrusion 250 to form the connection between an electrode layer above the absorber layer of the solar cell and the second electrically conductive substrate. Some embodiments may use a solid protrusion while some embodiments may use a protrusion with a hollow center or non-solid center 252. Some may remove more material in areas away from the tip to minimize any strength loss in the tip area. The protrusion 250 in the embodiments may be inserted from below and then upwards. The base of protrusion 250 may be shaped to be wider than that of the via, although sizes narrower than the via are not excluded from alternative embodiments. Residual void(s) can be filled with filler material 254 that are typically electrically conductive, but non-conductive are not excluded in alternative embodiments. Some embodiments may only fill with material 254 up to a portion that is lower than the top of layer 10. Another layer (not shown) may then be overlaid both layer 10 and the material 254 and the protrusion 250 to make the electrical connection.

Optionally, some embodiment may be configured to be inserted from the other direction and then downward into the via as seen in FIG. 12. The layer 10 (transparent conductive electrode and/or electrically conductive finger layer) can be used to couple to the protrusion 260. FIG. 12 shows that the lower portion may be surround by void space (filled or unfilled by material). Some embodiments may also heat the lower substrate to form an solder or other electrical connection at location 270.

FIG. 13 shows a top down view over one via wherein the fingers or electrical connections from layer 10 make a connection to the protrusion. Optionally, this may be shape of bottom of protrusion 260. The fingers 280 may be separate as shown or as a joined network. The finger 280 may bridge or span any gaps not filled by the void. Optionally, some embodiments may only selectively fill voids beneath the fingers 280. The connections may be by known techniques, such as but not limited to deposition of electrically conductive pastes that are then cured, soldering, welding, laser welding, or other attachment of electrically conductive material.

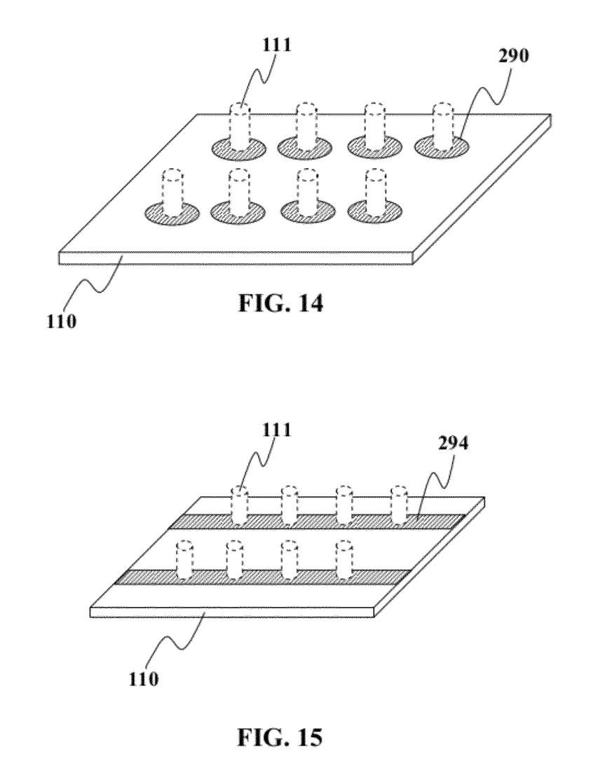

FIGS. 14 and 15 show that selective areas of the second substrate where the protrusion 111 are formed may be coated with one or more layers of other material. This coating may occur before the protrusion 111 is formed and/or after formation. In one embodiment, this layer may be a conductive layer more electrically conductive than that of the substrate being coated. As FIG. 14 shows, the additional layer may be applied in spots locations 290 or as in FIG. 15 in strips 294 (straight, curved, varying width, or other shaped). In some embodiments, the strips 294 may have a width less than that of the via to save material but still provide an area of good electrical contact. In some embodiments, the spots 290 may have a diameter less than that of the via to save material but still provide an area of good electrical contact.

It should also be understood that the foils 106 and/or 110 may be multi-layered. For example, some embodiments may have an electrically conductive substrate 110 comprised of a metalized polymer (outer metal layer over polymer core). Some embodiments may have two different metal layers such as an aluminum outer layer with a steel core or bottom layer. Some embodiments may have a plurality of opening in the more rigid steel layer with a thinner, flexible layer of aluminum or cooper on top of the more rigid, less conductive metal layer. The holes in the rigid metal layer may be aligned to match where the vias will be.

Overall electrical resistance is also reduced compared to designs where the via is filled using an electrically conductive material such as a silver based adhesive. This maybe due in part to the reduced distance between the second substrate 110 and the electrode layer and/or electrical trace above a photovoltaic absorber layer. Optionally, the reduced electrical resistance may be due to the reduced amount of conductive paste through which current will pass to reach the second substrate. Optionally, this may be due to a direct electrical contact between the back foil and the electrode layer and/or electrical trace above a photovoltaic absorber layer.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, traditional grid lines may also be used with some of the vias 20, although to minimize shadow loss, such use is limited to only select areas. In some embodiments, instead of vias, other geometric shapes such as but not limited to curved lines, variable width lines, squares or other shapes are used to provide a conductive pathway to the bottom electrode. Although most embodiments herein show solution deposition techniques, other vacuum or non-vacuum techniques may also be used to deposit materials to assist layer 10. Layer 10 may itself be integrated with or used over a transparent conductive layer such as a TCO, ZnO, ZnMO, ITO, or other transparent conductor as known.

Although the examples herein are discussed in terms of two metal foils, it should be understood that other embodiments using different materials for each layer are not excluded. Some embodiments may be used a metalized polymer substrate for one or both of the foil layers. Some embodiments may use polyimide or other material for at least one of the layers. Some may have one or more coatings on top of the foils to improve electrical conductivity. Some embodiments may have silver, nickel, or other material coated over the entire surface (or optionally, only at select locations) on foil 110. This may improve electrical conductivity at these locations, which in turn could be the locations where protrusions are formed.

The side walls of the via may be coated with electrically insulating material (not shown for ease of illustration) or have sufficient spacing to prevent electrical connection to the protrusion by layers of the solar cell except by the designated electrode layer and/or finger traces/busbars associated with the electrode layer.

It should also be understood that prior to deposition of any material on the substrate, the metal foil may undergo conditioning (cleaning, smoothening, and possible surface treatment for subsequent steps), such as but not limited to corona cleaning, wet chemical cleaning, plasma cleaning, ultrasmooth re-rolling, electro-polishing, and/or CMP slurry polishing.

Furthermore, those of skill in the art will recognize that any of the embodiments of the present invention can be applied to almost any type of solar cell material and/or architecture. For example, the absorber layer in the solar cell may be an absorber layer comprised of copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Many of these types of cells can be fabricated on flexible substrates. Examples of such solar cells include cells with active absorber layers comprised of silicon (e.g. for amorphous, micro-crystalline, or polycrystalline silicon cells), organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells), copper-indium-gallium-selenium (for CIG solar cells), cells whose active layer is comprised of CdSe, CdTe, and combinations of the above, where the active materials are present in any of several forms including but not limited to bulk materials, micro-particles, nano-particles, or quantum dots. Many of these types of cells can be fabricated on flexible substrates (e.g., stainless steel foil). Although these types of active layers can be manufactured in non-vacuum environments, the intra-cell and inter-cell electrical connection may use vacuum deposition of one or more metal conducting layers.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. Pat. No. 7,838,868, U.S. 20040219730, and U.S. 2005/0183767 are fully incorporated herein by reference for all purposes. U.S. Provisional Application Ser. No. 61/393,854, filed Oct. 15, 2010 is also fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A solar cell comprising:
a first metal substrate supporting an absorber layer thereon, wherein the metal substrate includes a plurality of vias extending through the first metal substrate;
a second electrically conductive substrate having a plurality of protrusions on at least one surface of the second electrically conductive substrate, the protrusions positioned to extend into the vias of the first metal substrate; and
an electrically insulating layer positioned to prevent direct electrical contact between a bottom surface of the first metal substrate and an upper surface of second electrically conductive substrate.

2. The cell of claim 1 wherein the protrusions have a cross-sectional profile with a hollow interior.

3. The cell of claim 1 wherein the protrusions are solid.

4. The cell of claim 1 wherein the protrusions are configured to reduce a top-side fill volume in each via.

5. The cell of claim 1 wherein the protrusions are configured to reduce a top-side fill volume in each via by at least 50%.

6. The cell of claim 1 wherein the protrusions are configured to reduce a top-side fill volume in each via by at least 75%.

7. The cell of claim 1 wherein the protrusions are configured to reduce a top-side fill volume in each via by at least 90% relative to completely filling each via without a protrusion therein.

8. The cell of claim 1 wherein the first metal substrate comprises one or more discrete layers formed over a bulk portion of the first metal substrate.

9. The cell of claim 1 wherein the second electrically conductive substrate has at least one high electrical conductivity on exposed surfaces of protrusions extending into the vias.

10. The cell of claim 1 wherein the second electrically conductive substrate has at least one high electrical conductivity silver-based layer on exposed surfaces of protrusions extending into the vias.

11. The cell of claim 1 wherein the protrusions comprises multiple metals.

12. The cell of claim 1 wherein the second electrically conductive substrate has at least one high electrical conductivity nickel-based layer on exposed surfaces of protrusions extending into the vias.

13. The cell of claim 1 wherein the protrusions extending into the vias has a cone-like shape.

14. The cell of claim 1 wherein the protrusions extending into the vias has a pyramid-like shape.

15. The cell of claim 1 wherein the protrusions extending into the vias has a cylindrical shape.

16. The cell of claim 1 wherein the protrusions wherein the second electrically conductive substrate is a metal substrate.

17. The cell of claim 1 wherein the protrusions when inserted into the via, has an uppermost portion above an uppermost surface of first metal substrate.

18. The cell of claim 1 wherein the protrusions when inserted into the via, has an uppermost portion below an uppermost surface of first metal substrate.

19. A method comprising:
constructing a solar cell with a conductive pathway between two vertically separated electrode layers creating protrusion in electrode material in at least one of the layers to extend through vias in the other electrode layer.

20. The method of claim 19 wherein creating the protrusions in the electrode material comprises using a punch to deform the electrode material.

21-32. (canceled)
